(19) United States
(12) Patent Application Publication
(10) Pub. No.: US 2022/0131138 A1
(43) Pub. Date: Apr. 28, 2022

(54) MATERIALS AND METHODS FOR COMPONENTS OF ZINC-ION BATTERIES

(71) Applicant: Lin CHEN, Chicago, IL (US)

(72) Inventor: Lin CHEN, Chicago, IL (US)

(21) Appl. No.: 17/310,875

(22) PCT Filed: Feb. 27, 2020
(86) PCT No.: PCT/US20/20190

§ 371 Date: Aug. 27, 2021

Related U.S. Application Data
(60) Provisional application No. 62/811,028, filed on Feb. 27, 2019.

(51) Int. Cl. H01M 4/50; H01M 4/04; H01M 10/36; H01M 4/52; H01M 4/58

(52) U.S. Cl. CPC H01M 4/50; H01M 4/0428; H01M 2300/0002; H01M 4/521; H01M 4/5825; H01M 10/36

(57) ABSTRACT

The present invention relates to materials and methods for components of zinc-ion batteries, such as manganese oxide cathodes having a coating. The coating comprises an oxide compound, a nitride compound, a fluoride compound, a phosphate compound, a sulfide compound, or any combination thereof.

### CROSS REFERENCE TO RELATED APPLICATIONS

This application claims benefit of the filing date and right of priority to U.S. Provisional Application No. 62/811,028, filed on Feb. 27, 2019, which is incorporated by reference herein.

### FIELD

The present invention relates to manganese oxide, cathodes and other components of zinc ion batteries.

### BACKGROUND

Power outages and interruptions can occur during and after extreme weather events, such as storms and ice. Not only do these affect the economy, costing the U.S. economy as much as $79 billion/year, but also these can result in dangers to public health and human safety. The energy storage system is one of the best solutions to address the problems caused by power outages, especially in remote places. However, at present, there is no battery system that can be transported easily and safely, run at a very effective cost with high energy density, and be recharged for a long cycle life.

Energy storage batteries have been a very rapid development industry to meet the ever-increasing energy needs. Mild aqueous zinc ion battery systems have attracted a lot of attention. On one hand, zinc metal has an ultrahigh theoretical capacity (819 mA h/g or 5850 A h/L) and is abundant and easy to transport and store. On the other hand, compared with organic electrolytes and alkaline electrolyte, mild aqueous electrolytes that do not lead to dendrite zinc are much safer and much cheaper, and also open possibilities for wide range temperature operation. Many types of cathodes to pair with Zn metal have been explored, and MnO₂ shows a promising discharge capacity and has a relatively low price. The operation voltage of Zn-MnO₂ is 1.8 V to 1 V, which makes the aqueous electrolyte stable over a long cycle life.

Therefore, mild aqueous zinc/manganese oxide batteries are highly desirable for large-scale energy storage applications owing to their low-cost, high safety and high energy density. However, the development of zinc/manganese oxide battery systems has been impeded by the rapid capacity decay observed in such systems, which is caused by the dissolution of MnO₂ into the electrolyte and the structural changes of MnO₂ from Zn-ions intercalation in the framework.

Different efforts have been tried to improve the stability of MnO₂ cathodes, such as by using carbon-based materials, especially graphene, to coat or mix with the cathode materials. The carbon materials can be used to improve the electrical conductivity of MnO₂ cathode materials and improve stability, and there have been promising results, especially the graphene coated MnO₂. For instance, Wu et al., “Graphene Scroll-Coated α-MnO₂ Nanowires as High-Performance Cathode Materials for Aqueous Zn-Ion Battery”, Small 2018, 14, 1703850, states that it demonstrates a highly reversible aqueous zinc ion battery (ZIB) using α-MnO₂/graphene scrolls (MGS) as the cathode material. Wu et al. discloses a method of preparing α-MnO₂ nanowires by hydrothermal technique and using Hummer's method to coat graphene onto the α-MnO₂ nanowires. The battery demonstrates high capacities and good stability. However, graphene is expensive, and its preparation and use for zinc-ion batteries would increase the cost of these low-cost batteries, reducing their competitiveness in price and their scope of potential distribution.

Pan et al., “Reversible aqueous zinc/manganese oxide energy storage from conversion reactions”, Nature Energy 2016, 1, 16039, states that it demonstrates a highly reversible zinc/manganese oxide system in which optimal mild aqueous ZnSO₄-based solution is used as the electrolyte, and nanofibres of a non-commericial and relative expensive manganese oxide phase, α-MnO₂, are used as the cathode. Xu et al., “Preparation and Characterization of MnO₂/acid-treated CNT Nanocomposites for Energy Storage with Zinc Ions”, Electrochimica Acta 2014, 133, 254, discusses α-MnO₂ nanorods deposited onto carbon nanotubes, which were tested with mild aqueous electrolytes for zinc-ion batteries.

Kang et al. US Pat. App. Publication No. 20120034515 A1 discusses a rechargeable zinc ion battery. Kang et al. US Pat. App. Publication No. 20150287988 A1 discusses a rechargeable battery based on reversible manganese oxidation and reduction reaction on carbon/manganese dioxide composites. Yadav et al. US Pat. App. Publication No. 20190044129 A1 discusses rechargeable alkaline manganese dioxide-zinc bipolar batteries. Wilkinson et al. US Pat. App. Publication No. 20190237762 A1 discusses a manganese oxide composition and method for preparing manganese oxide composition.

### SUMMARY

As one aspect of the present invention, an improved manganese oxide cathode is provided. The manganese oxide cathode comprises a substrate comprising manganese oxide; and a coating on the substrate, wherein the coating comprises an oxide compound, a nitride compound, a fluoride compound, a phosphatecompound, a pure metal or metalloid, a sulfide compound, or any combination thereof.

As another aspect, the present invention provides an improved zinc-ion battery comprising a manganese oxide cathode as described herein; an anode comprising zinc; a separator for separating the cathode from the anode; and an aqueous electrolyte.

As another aspect, methods are provided for preparing a manganese oxide cathode material or a zinc anode material for zinc-ion batteries. The method comprises forming a coating on a manganese oxide substrate or a zinc substrate by atomic layer deposition (ALD), spatial ALD, plasma enhanced atomic layer deposition (PEALD), any other ALD-based technologies, chemical vapor deposition (CVD), plasma enhanced chemical vapor deposition (PECVD), sputtering, physical vapor deposition (PVD), spinning coating, dip coating, pulsed laser deposition (PLD), spray coating or any combination thereof.

These and other features and advantages of the present methods and compounds will be apparent from the following detailed description, in conjunction with the appended claims.

### BRIEF DESCRIPTION OF THE DRAWINGS

FIGS. 1A and 1B show the capacity and the energy density of coin cells at 0.5 C with zinc metal and an embodiment of the present manganese oxide cathode.

FIG. 2 shows the capacity and the energy density of coin cells at 1.0 C with zinc metal and an embodiment of the present manganese oxide cathode.

FIG. 3 shows the Coulombic efficiency of coin cells at 0.5 C with zinc metal and an embodiment of the present manganese oxide cathode.

FIG. 4 shows the capacity of coin cells at 0.5 C at room temperature comprising an embodiment of the present manganese oxide cathode.

The present teachings are best understood from the following detailed description when read with the accompanying drawing figures. The features are not necessarily drawn to scale. Wherever practical, like reference numerals refer to like features.

### DETAILED DESCRIPTION

The present disclosure provides a scalable technique to make a thin coating on the manganese oxide cathodes or manganese oxide powders, and it can improve zinc-ion battery performance greatly.

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used herein, a “battery” refers to any container in which chemical energy is converted into electricity and used as a source of power. The terms battery and cell are generally interchangeable when referring to one electrochemical cell, although the term battery can also be used to refer to a plurality or stack of electrically interconnected cells. A battery includes an anode and a cathode operationally connected by an electrolyte, and typically includes various other battery components such as separators, current collectors, and housings. A “zinc ion battery” or Zn-ion battery (often abbreviated as ZIB) uses zinc ions (Zn²) as the charge carriers. ZIBs often utilize Zn as the anode, Zn-intercalating materials as the cathode, and a Zn-containing electrolyte. A rechargeable zinc ion battery typically comprises a cathode, a zinc anode, a separator for separating the cathode from the anode, and a liquid electrolyte containing zinc ions.

In the present disclosure, the terms “coating” and “film” generally have the same meaning unless the context indicates otherwise. As will be apparent from the present disclosure, a thin film may function as a protective coating, and a protective coating may have one or more physical characteristics of a thin film.

As used herein, a “layer” refers to a structure having length, width and thickness, and generally the thickness is smaller than length and/or width. A layer generally comprises opposing major surfaces defined by the length and width and separated from each other by the thickness. Layers can be selected to possess one or more properties, such as permeability, conductivity, or others. For instance, layers can be permeable, semipermeable, or substantially impermeable, wherein permeability is determined with respect to one or more substances. Layers can be electrically conductive, semi-conductive or insulating. A thin layer is one where the thickness is much smaller than length and/or width, such as where the thickness is at least 10^{x} smaller the length and/or width, where x is −3, −4, −5, −6, −7, −8 or a lower negative number.

Throughout this disclosure, any single layer of the cathodes or anodes described herein can have a thickness of at least 200 nm, or 500 nm, or 750 nm, or 1 μm, or 2 μm, or 5 μm, or 7.5 μm, or 10 μm, or 20 μm, or 25 μm, or 50 μm; and/or a thickness of at most 500 μm, or 400 μm, or 300 μm, or 200 μm, or 150 μm, or 125 μm, or 100 μm, or 90 μm, or 75 μm, or 60 μm. It is contemplated that any of these minimums and maximums can be combined to form a range (e.g., a thickness from 20 to 200 μm, and that any of these values can be approximate (e.g., about 50 μm). Any of the protective coatings, thin layers or inert layers described herein can have a thickness of at least 0.1 nm, or 0.5 nm, or 1 nm, or 2 nm, or 5 nm, or 10 nm, or 25 nm, or 50 nm, or 100 nm, or 250 nm, or 500 nm, or 1 μm, or 5 μm; and/or a thickness of at most 500 nm, or 1 μm, or 2.5 μm, or 5 μm, or 7.5 μm, or 10 μm, or 20 μm, or 25 μm, or 50 μm. It is contemplated that any of these minimums and maximums can be combined to form a range (e.g., a thickness from 0.1 nm to 500 nm, and that any of these values can be approximate (e.g., about 250 nm).

In the present disclosure, various depositions techniques are employed for creating or applying layers. For instance, a protective layer can be formed on a metal layer by chemical vapor deposition or atomic layer deposition. In chemical vapor deposition (CVD), a substrate is exposed to one or more precursors which react on the substrate to produce the deposited layer or film. Atomic layer deposition (ALD) is a chemical vapor deposition where precursors are sequentially provided to react with a surface (such as a substrate or a previously deposited layer of precursor). By repeated exposure to separate precursors, a thin film is deposited. Other deposition techniques which may be used in accordance with the present disclosure are spatial atomic layer deposition, plasma enhanced atomic layer deposition, plasma enhanced chemical vapor deposition, sputtering, physical vapor deposition, spinning coating, dip coating, spray coating or pulsed laser deposition. Spatial atomic layer deposition (SALD) is based on separating the precursors in space rather than in time. With SALD, one may avoid the step of purging precursors as typically done in ALD, so faster deposition rates are achievable. “Plasma enhanced” deposition techniques employ gases that have been partially ionized, and high energy electrons in the plasmas can be used to disassociate precursors or reactants into highly reactive radicals.

Manganese dioxide is commonly used in the production of alkaline zinc-ion batteries, such as alkaline Zn/MnO₂ batteries. In general, alkaline Zn/MnO₂ batteries comprise a cathode (i.e., one that comprises manganese dioxide as a cathodic active material), an anode (i.e., one that comprises zinc metal as an anodic active material), and an alkaline electrolytic solution (e.g., a potassium hydroxide solution) with which both the cathode and the anode are in fluid communication. During operation of an alkaline Zn/MnO₂ battery, zinc anodic material is oxidized, cathodic active material is reduced, and an electric current directed towards an external load is generated.

The present manganese oxide material can be provided as a manganese oxide cathode or a manganese oxide powder. The manganese oxide powder can be made into a cathode or other structure. Usually, cathodes can be prepared by mixing the manganese oxide powder with a conductive material (such as acetylene black) and a binder (such as polytetrafluoroethylene) in a solvent. After mixing, the cathode laminate is formed before the mixed materials are casted onto current collector substrates (such as carbon foam or aluminum) and dried.

As used herein, a “manganese oxide cathode” refers to an electrically conductive structure that comprises an amount of manganese oxide with condutive materials sufficient to provide or contribute to its conductivity. An example of a manganese oxide composition is manganese dioxide (MnO₂). Manganese dioxide exists in different polymorphs or phases. Such polymorphs include, but are not limited to, alpha-MnO₂, beta-MnO₂ (pyrolusite), gamma-MnO₂ (ramsdellite), and epsilon-MnO₂ (akhtenskite). The present material and methods can employ any of these polymorphs or mixtures thereof. In some embodiments, the present material comprises gamma-MnO₂, also called electrolytic manganese dioxide (EMD), which is large-scale commercial and relatively inexpensive. Other examples of manganese oxides are manganese (II, III) oxide, Manganese (II, III) oxide is present in nature in the mineral hausmannite, and may be used as a precursor material in the production of ceramic materials such as, but not limited to, magnets. The various chemical formulae of manganese (II, III) oxides may be generally identified as Mn₃O₄. Another example of a manganese oxide is Mn₂O₃, which is present in nature in the mineral bixbyite.

In a first aspect, the present disclosure provides a method of preparing a thin coating. The method may include: atomic layer deposition (ALD), chemical vapor deposition (CVD), plasma enhanced chemical vapor deposition (PECVD), sputtering, physical vapor deposition (PVD), plasma enhanced atomic layer deposition (PEALD), spinning coating, dip coating, spray coating, pulsed laser deposition (PLD), or any combination thereof.

In a second aspect, the present disclosure covers the material composition of such coating. Metalloid elements are boron, silicon, germanium, carbon, selenium, antimony, tellurium, polonium, and astatine.

The coating can comprise an oxide compound, including but not limited to zinc oxide, aluminum oxide, titanium oxide, hafnium oxide, zirconium dioxide, lithium oxide, lanthanum oxide, antimony tetroxide, antimony pentoxide, arsenic trioxide, arsenic pentoxide, barium oxide, bismuth oxide, bismuth oxide, calcium oxide, cerium oxide, cerium oxide, chromium oxide, chromium oxide, chromium oxide, chromium oxide, cobalt oxide, cobalt oxide, cobalt oxide, copper oxide, copper oxide, iron oxide, iron oxide, lead oxide, magnesium oxide, manganese oxide, mercury oxide, nickel oxide, rubidium oxide, silicon dioxide, silver oxide, thallium oxide, thallium oxide, thorium oxide, tin oxide, uranium oxide, tungsten oxide, selenium dioxide, tellurium dioxide.

The coating can comprise a nitride compound, including but not limited to boron nitride, zinc nitride, aluminum nitride, titanium nitride, hafnium nitride, zirconium nitride, lithium nitride, lanthanum nitride, barium nitride, bismuth nitride, bismuth nitride, calcium nitride, cerium nitride, cerium nitride, chromium nitride, chromium nitride, chromium nitride, chromium nitride, cobalt nitride, cobalt nitride, cobalt nitride, copper nitride, copper nitride, iron nitride, iron nitride, lead nitride, magnesium nitride, manganese nitride, mercury nitride, nickel nitride, rubidium nitride, silicon nitride, silver nitride, thallium nitride, thallium nitride, thorium nitride, tin nitride, uranium nitride, tungsten nitride, selenium nitride, tellurium nitride.

The coating can comprise a carbide compound, including but not limited to zinc carbide, aluminum carbide, titanium carbide, hafnium carbide, zirconium carbide, lithium carbide, lanthanum carbide, barium carbide, bismuth carbide, bismuth carbide, calcium carbide, cerium carbide, cerium carbide, chromium carbide, chromium carbide, chromium carbide, chromium carbide, cobalt carbide, cobalt carbide, cobalt carbide, copper carbide, copper carbide, iron carbide, iron carbide, lead carbide, magnesium carbide, manganese carbide, mercury carbide, nickel carbide, rubidium carbide, silicon carbide, silver carbide, thallium carbide, thallium carbide, thorium carbide, tin carbide, uranium carbide, tungsten carbide, selenium carbide, tellurium carbide.

The coating can comprise a fluoride compound, including but not limited to zinc fluoride, aluminum fluoride, titanium fluoride, hafnium fluoride, zirconium fluoride, lithium fluoride, lanthanum fluoride, barium fluoride, bismuth fluoride, bismuth fluoride, calcium fluoride, cerium fluoride, cerium fluoride, chromium fluoride, chromium fluoride, chromium fluoride, chromium fluoride, cobalt fluoride, cobalt fluoride, cobalt fluoride, copper fluoride, copper fluoride, iron fluoride, iron fluoride, lead fluoride, magnesium fluoride, manganese fluoride, mercury fluoride, nickel fluoride, rubidium fluoride, silicon fluoride, silver fluoride, thallium fluoride, thallium fluoride, thorium fluoride, tin fluoride, uranium fluoride, tungsten fluoride, selenium fluoride, tellurium fluoride.

The coating can comprise metal phosphate compounds, including but not limited to zinc phosphate, aluminum phosphate, titanium phosphate, hafnium phosphate, zirconium phosphate, lithium phosphate, lanthanum phosphate, barium phosphate, bismuth phosphate, bismuth phosphate, calcium phosphate, cerium phosphate, cerium phosphate, chromium phosphate, chromium phosphate, chromium phosphate, chromium phosphate, cobalt phosphate, cobalt phosphate, cobalt phosphate, copper phosphate, copper phosphate, iron phosphate, iron phosphate, lead phosphate, magnesium phosphate, manganese phosphate, mercury phosphate, nickel phosphate, rubidium phosphate, silicon phosphate, silver phosphate, thallium phosphate, thallium phosphate, thorium phosphate, tin phosphate, uranium phosphate, tungsten phosphate, selenium phosphate, tellurium phosphate.

The coating can comprise a pure metal or other elementary substrate (such as a pure metalloid), including but not limited to zinc, copper, carbon, gold, magnesium, aluminum, silicon, calcium, titanium, vanadium, chromium, manganese, iron, cobalt, nickel, copper and gallium.

The coating can comprise a sulfide compound, including but not limited to zinc sulfide, aluminum sulfide, titanium sulfide, hafnium sulfide, zirconium sulfide, lithium sulfide, lanthanum sulfide, barium sulfide, bismuth sulfide, bismuth sulfide, calcium sulfide, cerium sulfide, cerium sulfide, chromium sulfide, chromium sulfide, chromium sulfide, chromium sulfide, cobalt sulfide, cobalt sulfide, cobalt sulfide, copper sulfide, copper sulfide, iron sulfide, iron sulfide, lead sulfide, magnesium sulfide, manganese sulfide, mercury sulfide, nickel sulfide, rubidium sulfide, silicon sulfide, silver sulfide, thallium sulfide, thallium sulfide, thorium sulfide, tin sulfide, uranium sulfide, tungsten sulfide, selenium sulfide, tellurium sulfide.

The coating material can be any above material combination thereof.

In a third aspect, the present disclosure covers the thickness of the coating material made by the coating technologies listed above onto the MnO₂ cathode or the MnO₂ powder substrate. The thickness of the coating can range from 0.1 nanometers to 50 microns. The particular interest of the thickness can be narrowed down to 0.1 nm to 500 nm.

The present battery systems can comprise an electrolyte. Electrolytes generally comprise a solvent and a solute. In some embodiments of the present batteries, the solvent is water, and the solute is a zinc ion or zinc compound, such as zinc nitride, zinc chloride, and/or zinc sulfate. In some embodiments, the electrolyte is a mild electrolyte, having a pH value from about 4 to about 7 during storage and/or operation. In some embodiments, the electrolyte has a pH value during storage and/or operation that is at least 4, or at least 4.5, or at least 5, or at least 5.5, or at least 6, or at least 6.2, or at least 6.4. In some embodiments, the electrolyte has a pH value during storage and/or operation that is at most 7.5, or at most 7.4, or at most 7.2, or at most 7, or at most 6.8. Any of these minimums and maximums can be combined to form a range. To enable the electrolyte to function at low temperature, such as below zero Celsius, the electrolyte may include one or more additives to prevent the water from freezing at the low temperature. The additives can be some organic solution or metal salts for the purpose of lowering the water freezing temperature, including but not limited to propylene glycol and salts, such as zinc chloride, calcium chloride, sodium chloride and magnesium chloride.

To increase the electrolyte wettability on the zinc-based metal anode, coatings are also applied on the surface. The lists of coating technologies, materials and thickness can be the same claims as listed above for the cathodes. Alternatively or additionally, the coating for the zinc-based metal anode can comprise a compound having one or more hydroxyl or carboxyl groups such as cellulose; a saccharide (such as glucose), oligosaccharide, or polysaccharide; a (meth)acrylic acid or (meth)acrylate and polymers thereof; a nitride compound with a N—H group; NO₂; a compound having a carbon-nitrogen structure such as urethane and leucine; a phosphate compound such as zinc phosphate; or any combination thereof.

The present batteries can also include one or more separators. A separator is usually is a thin layer of a suitable material, which can physically separate an anode from a cathode. The separator is generally nonoxidizable and stable in the battery environment.

In one example, the present disclosure provides a method of preparing advanced materials coated MnO₂ cathodes as the cathodes of zinc-ion batteries, wherein the method comprises:
a) employing MnO₂ powders or MnO₂ cathodes including binders and conductives in the electrode as the substrate;
b) using the technical methods, such as CVD, PECVD, ALD, sputtering, PVD, PEALD, spinning coating, dip coating, PLD, to make a coating onto the substrate.
c) The coating material can be any kind, and the list is presented above.
wherein the coating thickness can range from 0.1 nanometers to 50 microns. The particular interest of the thickness can be narrowed down to 0.1 nm to 500 nm.

In one example, the present disclosure provides a method of preparing advanced materials coated MnO₂ cathodes as the cathodes of zinc-ion batteries, wherein the method comprises:
a) employing MnO₂ powders or MnO₂ cathodes including binders and conductive in the electrode as the substrate;
b) using the ALD and ALD-based technologies to make a coating onto the substrate.
c) The coating material can be any kind, and the list is presented above.
wherein the coating thickness can range from 0.1 nanometers to 50 microns. The particular interest of the thickness can be narrowed down to 0.1 nm to 500 nm.

In any example of the present disclosure, the prepared coating is substantially homogeneous and greatly uniform in compositions and thickness.

To enable the operation of mild aqueous MnO₂ cathodes coupled with zinc anodes under very low temperature, such as −40° C., additives to prevent the water from freezing will be added into the electrolyte, including but not limited to propylene glycol.

A zinc-ion battery typically includes an anode and a cathode separated by an electrically insulating barrier or separator, and the electrolyte medium typically includes one or more salts and a solvent such as water or an organic material.

As one aspect of the present invention relates to the use of advanced materials to coat MnO₂ cathodes and zinc anodes. These advanced materials are formed as thin films. The thin films can be applied by thin film deposition techniques, including, but not limited to, chemical vapor deposition, atomic layer deposition, pulsed laser deposition, physical vapor deposition, dip coating, spin coating, electroplating, or spray coating.

In some embodiments, the coating is a layer formed or coated on MnO₂, wherein the layer has a thickness from 0.1 nm to 50 microns. The coating can be formed on the MnO₂ layer, such as by being deposited on one or both major surfaces of the layer, and in some embodiments, one or both major surfaces of a layer are entirely covered by a coating.

The present cathodes and anodes can also comprise a current collector, such as copper, aluminum, carbon or stainless steel. For example, a cathode layer may have first and second major surfaces, and a protective coating may be disposed on the first major surface and a current collector may be disposed on the second major surface.

In some embodiments, the coating or one or more layers of the coating comprises an oxide compound, a nitride compound, a fluoride compound, a phosphate compound, a sulfide compound, or any combination thereof. The layer can be formed one or both major surfaces by atomic layer deposition, plasma enhanced atomic layer deposition, chemical vapor deposition, plasma enhanced chemical vapor deposition, sputtering, physical vapor deposition, spinning coating, dip coating, spray coating, or pulsed laser deposition.

The MnO₂ cathodes having a coating as described herein can be used to solve several problems, such as dissolution of MnO₂ into an aqueous electrolyte and change of MnO₂ structure upon the Zn ions intercalation, though not every embodiment necessarily solves every problem. Putting a protective coating or thin film on the cathode will suppress MnO₂ loss and the MnO₂ structure change.

The present metal anodes can be incorporated into and configured for use in zinc-ion batteries, such as cylindric cells and pouch cells. In some embodiments, the present disclosure provides batteries having: (a) a battery energy density of around 220 Wh/kg or higher (cell level) and/or 180 Wh/kg or higher (battery level), or around 300 Wh/L (cell level) or higher based on volume energy density; (b) much improved cycle life with the coating on MnO₂ cathodes compared to the bare MnO2 cathodes.

The present MnO₂ cathodes can be incorporated into and configured for use in zinc-ion batteries for consumer electronics, home-use energy storage and large-scale utility energy storage. Any other areas that need power sources, especially with requirement for great safety, the present technology can find an application.

As another aspect of the present invention, novel anodes and battery components are provided. The anodes comprise a coating on a zinc metal layer. In some embodiments, the anodes comprise one of the coatings described above. In other embodiments, other battery components comprise a coating as described above on a battery component layer or material. In some embodiments, the zinc metal layer comprises pure zinc or a zinc alloy. The zinc metal layer can be in any shape, such as a foil, film, plat, grid, pillar, etc.

In some embodiments, the cathode material can be nanosized or microsized powder, and/or the cathode material can be MnO₂ powders, and/or the cathode can comprise two or more layers of the cathode material.

As another aspect, a process for preparing a cathode is provided. The process comprises depositing a thin layer of inert material onto a layer of cathode material by dip coating, sputter coating, chemical vapor deposition, atomic layer deposition, or spin coating on the surface of a cathode material as powders or a cathode laminate, wherein the powders can be made by any approach, including sol-gel method, solid state reactions, ultrasonic spray pyrolysis, flame-assisted pyrolysis, liquid-feed flame spray pyrolysis, or co-precipitation. The cathode is configured for use as a cathode in a zinc-ion battery.

In some embodiments, the thin layer is formed by atomic layer deposition, plasma enhanced atomic layer deposition, chemical vapor deposition, plasma enhanced chemical vapor deposition, sputtering, physical vapor deposition, spinning coating, dip coating, spray coating, or pulsed laser deposition. Preferably, the protective layer is formed by atomic layer deposition or plasma enhanced atomic layer deposition.

In some embodiments of the present cathode or process, the cathode material is made with average diameter of 50 nm to 50 μm powders and/or the cathode material is mixed with a binder and conductive additives for a cathode as a laminate. For example, the process can comprise forming a laminate layer from a cathode material powder, which has a suitable particle size, such as a mean particle size from 50 nm to 50 μm, or from 500 nm to 10 μm.

The coating material precursors can be manipulated to tune the element ratio in the material. Some material precursors can be metal organics which permit the material synthesis to be performed at low temperatures (e.g., from 80° C. to 300° C.). The synthesized material can then be sintered at high temperature if desired.

In some embodiments, some material precursors are inorganics and reacts with the metal organics to form oxide, nitride or phosphates etc. The material synthesis can be performed at relatively high temperature (e.g., 300° C.-1200° C.).

In some embodiments, a chemical vapor based technology, such as atomic layer deposition and chemical vapor deposition, to make a thin film or protective coating on cathode material powders or onto cathode laminates after casting of cathode material powders onto current collectors. The present process can also comprise forming a laminate by mixing the cathode material with a binder and conductive additives. For example, the cathode material, the binder, and the conductive additives can be cast onto a current collector before forming the laminate.

As noted above, spatial atomic layer deposition (SALD) is based on separating the precursors in space rather than in time. This can improve the efficiency of ALD precursor dosing and pump usage so as to reduce the cost and maintenance of applying the thin layers. SALD can be used to directly coat the MnO₂ powers, but also employed to coat the cathode laminate. With a continuous and efficient roll-to-roll process, fast production (>5 meters/min) can be accomplished for large scale production, and the cost of material production can be decreased significantly to achieve the cost of final battery products at relatively low cost.

The plurality of deposition zone can comprise at least a first deposition zone comprising a first coating material precursor that reacts or decomposes on a MnO₂ cathode layer, and a second deposition zone comprising a second coating material precursor that reacts or decomposes on the first coating material precursor. For example, the first coating material precursor can be diethylzinc and the second coating material precursor can be water.

The cathodes, anodes, electrolytes, and other components described herein can be incorporated into batteries or other electrochemical cells. For example, the MnO₂ cathodes and other components can be assembled into various battery designs such as cylindrical batteries, prismatic shaped batteries, pouch cell batteries, or other battery shapes. The batteries can comprise a single pair of electrodes or a plurality of pairs of electrodes assembled in parallel and/or series electrical connection(s). While the materials described herein can be used in batteries for primary, or single charge use, the MnO₂ cathodes, anodes, electrolytes and other components generally have desirable properties for incorporation in secondary batteries (or rechargeable batteries) which are capable of use over multiple cycles of charge and discharge. The batteries can be configured as coin cells, pouch cells, or other cells.

In the present disclosure the term “substantially” can allow for a degree of variability in a value or range, for example, within 80%, within 85%, within 90%, within 95%, or within 99% of a stated value or of a stated limit of a range.

In the present disclosure the term “about” can allow for a degree of variability in a value or range, for example, within 20%, within 10%, within 5%, or within 1% of a stated value or of a stated limit of a range.

In the present disclosure, numeric ranges are inclusive of the numbers defining the range. It should be recognized that chemical structures and formula may be elongated or enlarged for illustrative purposes.

Whenever a range of the number of atoms in a structure is indicated (e.g., a C₁-C₂₄ alkyl, C₂-C₂₄ alkenyl, C₂-C₂₄ alkynyl, etc.), it is specifically contemplated that the substituent can be described by any of the carbon atoms in the sub-range or by any individual number of carbon atoms falling within the indicated range. By way of example, a description of the group such as an alkyl group using the recitation of a range of 1-24 carbon atoms (e.g., C₁-C₂₄), specifically describes an alkyl group having any of 1, 2, 3, 4, 5, 6, 7, 8, 9, 10, 11, 12, 13, 14, 15, 16, 17, 18, 19, 20, 21, 22, 23 and 24 carbon atoms, as appropriate, as well as any sub-range thereof (e.g., 1-2 carbon atoms, 1-3 carbon atoms, etc.).

Unless defined otherwise, all technical and scientific terms used herein have the same meaning as commonly understood by those working in the fields to which this disclosure pertain.

Before the various embodiments are described, it is to be understood that the teachings of this disclosure are not limited to the particular embodiments described, and as such can, of course, vary. It is also to be understood that the terminology used herein is for the purpose of describing particular embodiments only, and is not intended to be limiting, since the scope of the present teachings will be limited only by the appended claims.

As disclosed herein, a number of ranges of values are provided. It is understood that each intervening value, to the tenth of the unit of the lower limit, unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present teachings, some exemplary methods and materials are now described.

All patents and publications referred to herein are expressly incorporated by reference.

As used in the specification and appended claims, the terms “a,” “an,” and “the” include both singular and plural referents, unless the context clearly dictates otherwise. Thus, for example, “a layer” includes one layer and plural layers. The term “or” between alternatives includes “and/or”, unless the context clearly dictates that only one alternative can be present.

In view of this disclosure it is noted that the methods can be implemented in keeping with the present teachings. Further, the various components, materials, structures and parameters are included by way of illustration and example only and not in any limiting sense. In view of this disclosure, the present teachings can be implemented in other applications and components, materials, structures and equipment to implement these applications can be determined, while remaining within the scope of the appended claims.

### EXEMPLARY EMBODIMENTS

To assist in understanding the scope and benefits of the present invention, the following description of exemplary or preferred embodiments is provided. The exemplary embodiments should be taken as illustrating, rather than as limiting, the present invention as defined by the claims. As will be readily appreciated, numerous variations and combinations of the features set forth above can be utilized without departing from the present invention as set forth in the claims. Such variations are not regarded as a departure from the scope of the invention, and all such variations are intended to be included within the scope of the following claims.

Embodiment 1. A manganese oxide cathode comprising a substrate comprising manganese oxide powders or manganese oxide laminate; and a coating on the substrate, wherein the coating comprises an oxide compound, a nitride compound, a fluoride compound, a phosphate compound, a sulfide compound, or any combination thereof.

Embodiment 2. The cathode of embodiment 1, wherein the coating is formed on the substrate layer by atomic layer deposition (ALD), thermal ALD, spatial ALD, plasma enhanced atomic layer deposition (PEALD), chemical vapor deposition (CVD), dip coating, or any combination thereof.

Embodiment 3. The cathode according to embodiment 1 or embodiment 2, wherein the coating comprises an oxide compound selected from the group consisting of zinc oxide, aluminum oxide, titanium oxide, hafnium oxide, zirconium dioxide, lithium oxide, lanthanum oxide, antimony tetroxide, antimony pentoxide, arsenic trioxide, arsenic pentoxide, barium oxide, bismuth oxide, bismuth oxide, calcium oxide, cerium oxide, cerium oxide, chromium oxide, chromium oxide, chromium oxide, chromium oxide, cobalt oxide, cobalt oxide, cobalt oxide, copper oxide, copper oxide, iron oxide, iron oxide, lead oxide, magnesium oxide, manganese oxide, mercury oxide, nickel oxide, rubidium oxide, silicon dioxide, silver oxide, thallium oxide, thallium oxide, thorium oxide, tin oxide, uranium oxide, tungsten oxide, selenium dioxide, tellurium dioxide, and combinations thereof.

Embodiment 4. The cathode according to embodiment 1 or embodiment 2, wherein the coating comprises a nitride compound selected from the group consisting of boron nitride, zinc nitride, aluminum nitride, titanium nitride, hafnium nitride, zirconium nitride, lithium nitride, lanthanum nitride, barium nitride, bismuth nitride, bismuth nitride, calcium nitride, cerium nitride, cerium nitride, chromium nitride, chromium nitride, chromium nitride, chromium nitride, cobalt nitride, cobalt nitride, cobalt nitride, copper nitride, copper nitride, iron nitride, iron nitride, lead nitride, magnesium nitride, manganese nitride, mercury nitride, nickel nitride, rubidium nitride, silicon nitride, silver nitride, thallium nitride, thallium nitride, thorium nitride, tin nitride, uranium nitride, tungsten nitride, selenium nitride, tellurium nitride, and combinations thereof.

Embodiment 5. The cathode according to embodiment 1 or embodiment 2, wherein the coating comprises a carbide compound selected from the group consisting of zinc carbide, aluminum carbide, titanium carbide, hafnium carbide, zirconium carbide, lithium carbide, lanthanum carbide, barium carbide, bismuth carbide, bismuth carbide, calcium carbide, cerium carbide, cerium carbide, chromium carbide, chromium carbide, chromium carbide, chromium carbide, cobalt carbide, cobalt carbide, cobalt carbide, copper carbide, copper carbide, iron carbide, iron carbide, lead carbide, magnesium carbide, manganese carbide, mercury carbide, nickel carbide, rubidium carbide, silicon carbide, silver carbide, thallium carbide, thallium carbide, thorium carbide, tin carbide, uranium carbide, tungsten carbide, selenium carbide, tellurium carbide, and combinations thereof.

Embodiment 6. The cathode according to embodiment 1 or embodiment 2, wherein the coating comprises a fluoride compound selected from the group consisting of zinc fluoride, aluminum fluoride, titanium fluoride, hafnium fluoride, zirconium fluoride, lithium fluoride, lanthanum fluoride, barium fluoride, bismuth fluoride, bismuth fluoride, calcium fluoride, cerium fluoride, cerium fluoride, chromium fluoride, chromium fluoride, chromium fluoride, chromium fluoride, cobalt fluoride, cobalt fluoride, cobalt fluoride, copper fluoride, copper fluoride, iron fluoride, iron fluoride, lead fluoride, magnesium fluoride, manganese fluoride, mercury fluoride, nickel fluoride, rubidium fluoride, silicon fluoride, silver fluoride, thallium fluoride, thallium fluoride, thorium fluoride, tin fluoride, uranium fluoride, tungsten fluoride, selenium fluoride, tellurium fluoride, and combinations thereof.

Embodiment 7. The cathode according to embodiment 1 or embodiment 2, wherein the coating comprises a phosphate compound selected from the group consisting of zinc phosphate, aluminum phosphate, titanium phosphate, hafnium phosphate, zirconium phosphate, lithium phosphate, lanthanum phosphate, barium phosphate, bismuth phosphate, bismuth phosphate, calcium phosphate, cerium phosphate, cerium phosphate, chromium phosphate, chromium phosphate, chromium phosphate, chromium phosphate, cobalt phosphate, cobalt phosphate, cobalt phosphate, copper phosphate, copper phosphate, iron phosphate, iron phosphate, lead phosphate, magnesium phosphatephosphate, manganese phosphate, mercury phosphate, nickel phosphate, rubidium phosphate, silicon phosphate, silver phosphate, thallium phosphate, thallium phosphate, thorium phosphate, tin phosphate, uranium phosphate, tungsten phosphate, selenium phosphate, tellurium phosphate, and combinations thereof.

Embodiment 8. The cathode according to embodiment 1 or embodiment 2, wherein the coating comprises a pure metal or metalloid selected from the group consisting of zinc, copper, carbon, gold, magnesium, aluminum, silicon, calcium, titanium, vanadium, chromium, manganese, iron, cobalt, nickel, carbon and gallium.

Embodiment 9. The cathode according to embodiment 1 or embodiment 2, wherein the coating comprises a sulfide compound selected from the group consisting of zinc sulfide, aluminum sulfide, titanium sulfide, hafnium sulfide, zirconium sulfide, lithium sulfide, lanthanum sulfide, barium sulfide, bismuth sulfide, bismuth sulfide, calcium sulfide, cerium sulfide, cerium sulfide, chromium sulfide, chromium sulfide, chromium sulfide, chromium sulfide, cobalt sulfide, cobalt sulfide, cobalt sulfide, copper sulfide, copper sulfide, iron sulfide, iron sulfide, lead sulfide, magnesium sulfide, manganese sulfide, mercury sulfide, nickel sulfide, rubidium sulfide, silicon sulfide, silver sulfide, thallium sulfide, thallium sulfide, thorium sulfide, tin sulfide, uranium sulfide, tungsten sulfide, selenium sulfide, tellurium sulfide, and combinations thereof.

Embodiment 10. The cathode according to any of the foregoing embodiments, wherein the coating has a thickness in a range from about 0.1 nanometers to about 50 microns, or from about 0.1 nm to about 500 nm.

Embodiment 11. The cathode according to any of the foregoing embodiments, wherein the coating is substantially homogeneous and conformal on the substrate.

Embodiment 12. The cathode according to any of the foregoing embodiments, wherein the manganese oxide is gamma-MnO2.

Embodiment 13. A zinc-ion battery comprising the manganese oxide cathode according to any of the foregoing embodiments; an anode comprising zinc; a separator for separating the cathode from the anode; and an aqueous electrolyte.

Embodiment 14. The zinc-ion battery of embodiment 13, wherein the electrolyte has a pH ranging from about 4 to about 7.

Embodiment 15. The zinc-ion battery of embodiment 13 or embodiment 14, wherein the electrolyte comprises an additive that lowers a freezing point of the electrolyte.

Embodiment 16. The zinc-ion battery of embodiment 13 or embodiment 14, wherein the electrolyte comprises zinc ions, manganese ions, and sulfate ions.

Embodiment 17. The zinc-ion battery according to any of embodiments 13 to 16, wherein the electrolyte comprises propylene glycol.

Embodiment 18. The zinc-ion battery according to any of embodiments 13 to 17, wherein the electrolyte comprises ions from salts selected from the group consisting of zinc chloride, calcium chloride, sodium chloride and magnesium chloride.

Embodiment 19. The zinc-ion battery according to any of embodiments 13 to 18, wherein the anode comprises a coating comprising an oxide compound, a nitride compound, a fluoride compound, a phosphate compound, a sulfide compound, or any combination thereof.

Embodiment 20. The zinc-ion battery according to any of embodiments 13 to 19, wherein the anode comprises a coating comprising a compound having one or more hydroxyl or carboxyl groups; a saccharide, oligosaccharide, or polysaccharide; a (meth)acrylic acid or (meth)acrylate and polymers thereof; a nitride compound with a N—H group; NO2; a compound having a carbon-nitrogen structure; a phosphate compound; or any combination thereof.

Embodiment 21. A method of preparing a manganese oxide cathode material for zinc-ion batteries, wherein the method comprises forming a coating on a manganese oxide substrate by atomic layer deposition (ALD), spatial ALD, plasma enhanced atomic layer deposition (PEALD), any other ALD-based technologies, chemical vapor deposition (CVD), plasma enhanced chemical vapor deposition (PECVD), dip coating, or any combination thereof.

Embodiment 22. The method of embodiment 21, wherein the coating comprises an oxide compound, a nitride compound, a fluoride compound, a phosphate compound, a pure metal or metalloid, a sulfide compound, or any combination thereof.

Embodiment 23. The method of embodiment 21 or embodiment 22, wherein the manganese oxide substrate comprises or is formed from a powder.

Embodiment 24. The method according to any of embodiments 21 to 23, wherein the manganese oxide substrate is a layer, and the layer further comprises a binder.

Embodiment 25. The method according to any of embodiments 21 to 24, wherein the coating on the manganese oxide substrate has a mean thickness from 0.1 nanometers to 50 microns.

Embodiment 26. A method of preparing a zinc anode material for zinc-ion batteries, wherein the method comprises forming a coating on a zinc substrate by atomic layer deposition (ALD), spatial ALD, plasma enhanced atomic layer deposition (PEALD), any other ALD-based technologies, chemical vapor deposition (CVD), plasma enhanced chemical vapor deposition (PECVD), sputtering, physical vapor deposition (PVD), spinning coating, dip coating, spray coating, pulsed laser deposition (PLD), or any combination thereof.

Embodiment 27. The method of embodiment 26, wherein the coating for the anode comprises an oxide compound, a nitride compound, a fluoride compound, a phosphate compound, a sulfide compound, or any combination thereof.

Embodiment 28. The method of embodiment 26 or embodiment 27, wherein the coating for the anode comprises a compound having one or more hydroxyl or carboxyl groups; a saccharide, oligosaccharide, or polysaccharide; a (meth)acrylic acid or (meth)acrylate and polymers thereof; a nitride compound with a N—H group; NO2; a compound having a carbon-nitrogen structure; a phosphate compound; or any combination thereof.

Embodiment 29. The method according to any of embodiments 26 to 28, wherein the coating on the zinc substrate has a mean thickness from 0.1 nanometers to 50 microns.

### EXAMPLES

### Example 1

In this example, an ZnO coating is deposited on a MnO₂ cathode laminate substrate using Atomic Layer Deposition (ALD).

To prepare the ZnO coated MnO₂, the materials are placed in the ALD reactors at 100° C. Five cycles of ALD ZnO, based on the reactions of diethylzinc and water as the precursors, is deposited onto the material substrates. The coating thickness was measured to be 1 nm. The ZnO coated MnO₂ is employed as the cathode and paired with the Zn metal anode along with mild electrolyte including MnSO₄ and ZnSO₄ aqueous electrolyte.

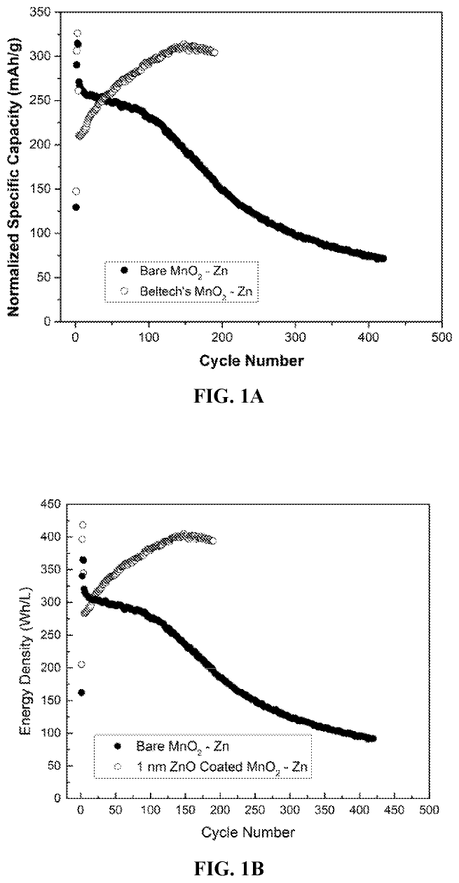

FIGS. 1A and 1B show the capacity and the energy density of coin cells at 0.5 C with a zinc metal anode and the ALD ZnO coated MnO₂ cathode. The battery testing results show that zinc-ion batteries will be a great alternative energy storage in terms of energy density, which is comprarable to state-of-the-art lithium ion batteries. The battery testing results show that zinc-ion batteries will be a great alternative energy storage in terms of energy density, which is comprarable to state-of-the-art lithium ion batteries. The ZnO coating on MnO2 demonstrates significant improvement of battery capacity compared to bare MnO2.

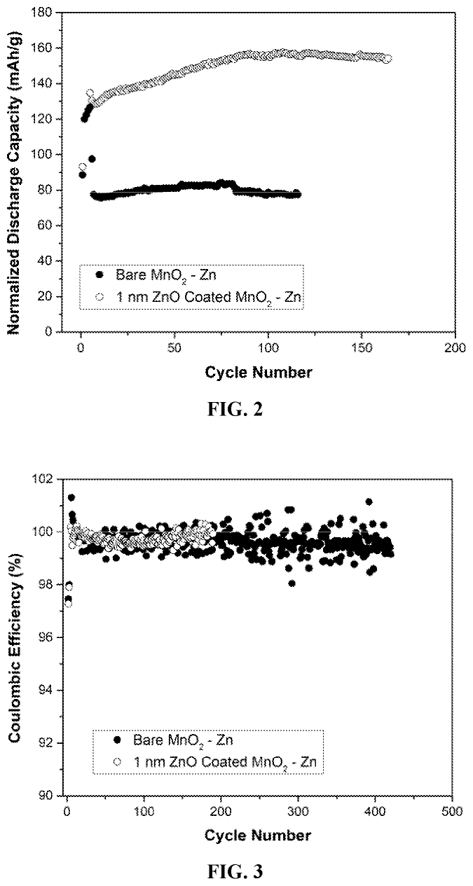

FIG. 2 shows the discharge capacity of bare MnO₂—Zn cell and coated MnO₂-Zn cell at 1.0 C under room temperature. The first three cycles of ZnO coated MnO₂ are tested at 0.1 C and the first 5 cycles of bare MnO₂ are tested at 0.1 C, followed by 1.0 C after the three cycles and the five cycles, respectively.

FIG. 3 shows the Coulombic efficiency of coin cells at 0.5 C with a zinc metal anode and the ALD ZnO coated MnO₂ cathode. The coin cell with the coated MnO₂ yields highly stable Coulombic efficiency of 99.5%-100%, compared to the unstable Coulombic efficiency of the coin cell with bare MnO₂.

### Example 2

In this example, an Al-doped ZnO coating is deposited on a MnO₂ cathode laminate substrate using Atomic Layer Deposition (ALD).

To prepare the Al-doped ZnO coated MnO₂, the materials are placed in the ALD reactors at 100° C. Trimethylaluminium (TMA), diethylzinc (DEZ) and water are sequentially dosed with the ratio of 1:1:1 to the ALD reactor where the cathode laminate is located. Four cycles of TMA, DEZ and water is deposited onto the material substrates. The resulted Al—ZnO (termed as “Al-doped ZnO”) coated MnO₂ is employed as the cathode and paired with the Zn metal anode along with mild electrolyte including MnSO₄ and ZnSO₄ aqueous electrolyte.

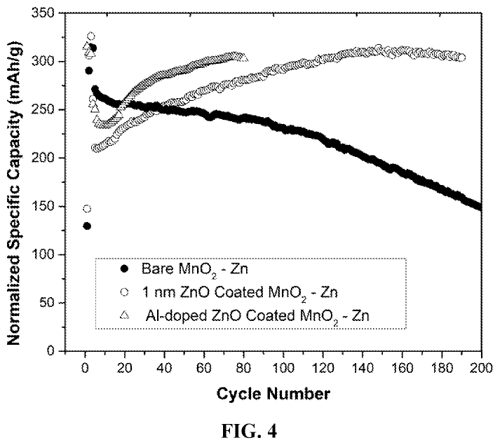

FIG. 4 shows the capacity of coin cells at 0.5 C at room temperature comprising a zinc metal anode and the ALD Al-doped ZnO coated MnO₂ cathode, compared to the cells with bare MnO₂ cathode and the ZnO coated MnO₂ cathode of Example 1. The obtained Al-doped ZnO coating obviously enables higher capacity for MnO₂ cathodes.

1. A manganese oxide cathode comprising:
a substrate comprising manganese oxide powders or manganese oxide laminate; and
a coating on the substrate, wherein the coating comprises an oxide compound, a nitride compound, a fluoride compound, a phosphate compound, a sulfide compound, or any combination thereof.

2. The cathode of claim 1, wherein the coating is formed on the substrate layer by atomic layer deposition (ALD), thermal ALD, spatial ALD, plasma enhanced atomic layer deposition (PEALD), chemical vapor deposition (CVD), dip coating, or any combination thereof.

3. The cathode of claim 1, wherein the coating comprises an oxide compound selected from the group consisting of zinc oxide, aluminum oxide, titanium oxide, hafnium oxide, zirconium dioxide, lithium oxide, lanthanum oxide, antimony tetroxide, antimony pentoxide, arsenic trioxide, arsenic pentoxide, barium oxide, bismuth oxide, bismuth oxide, calcium oxide, cerium oxide, cerium oxide, chromium oxide, chromium oxide, chromium oxide, chromium oxide, cobalt oxide, cobalt oxide, cobalt oxide, copper oxide, copper oxide, iron oxide, iron oxide, lead oxide, magnesium oxide, manganese oxide, mercury oxide, nickel oxide, rubidium oxide, silicon dioxide, silver oxide, thallium oxide, thallium oxide, thorium oxide, tin oxide, uranium oxide, tungsten oxide, selenium dioxide, tellurium dioxide, and combinations thereof.

4. The cathode of claim 1, wherein the coating comprises a nitride compound selected from the group consisting of boron nitride, zinc nitride, aluminum nitride, titanium nitride, hafnium nitride, zirconium nitride, lithium nitride, lanthanum nitride, barium nitride, bismuth nitride, bismuth nitride, calcium nitride, cerium nitride, cerium nitride, chromium nitride, chromium nitride, chromium nitride, chromium nitride, cobalt nitride, cobalt nitride, cobalt nitride, copper nitride, copper nitride, iron nitride, iron nitride, lead nitride, magnesium nitride, manganese nitride, mercury nitride, nickel nitride, rubidium nitride, silicon nitride, silver nitride, thallium nitride, thallium nitride, thorium nitride, tin nitride, uranium nitride, tungsten nitride, selenium nitride, tellurium nitride, and combinations thereof.

5. The cathode of claim 1, wherein the coating comprises a carbide compound selected from the group consisting of zinc carbide, aluminum carbide, titanium carbide, hafnium carbide, zirconium carbide, lithium carbide, lanthanum carbide, barium carbide, bismuth carbide, bismuth carbide, calcium carbide, cerium carbide, cerium carbide, chromium carbide, chromium carbide, chromium carbide, chromium carbide, cobalt carbide, cobalt carbide, cobalt carbide, copper carbide, copper carbide, iron carbide, iron carbide, lead carbide, magnesium carbide, manganese carbide, mercury carbide, nickel carbide, rubidium carbide, silicon carbide, silver carbide, thallium carbide, thallium carbide, thorium carbide, tin carbide, uranium carbide, tungsten carbide, selenium carbide, tellurium carbide, and combinations thereof.

6. The cathode of claim 1, wherein the coating comprises a fluoride compound selected from the group consisting of zinc fluoride, aluminum fluoride, titanium fluoride, hafnium fluoride, zirconium fluoride, lithium fluoride, lanthanum fluoride, barium fluoride, bismuth fluoride, bismuth fluoride, calcium fluoride, cerium fluoride, cerium fluoride, chromium fluoride, chromium fluoride, chromium fluoride, chromium fluoride, cobalt fluoride, cobalt fluoride, cobalt fluoride, copper fluoride, copper fluoride, iron fluoride, iron fluoride, lead fluoride, magnesium fluoride, manganese fluoride, mercury fluoride, nickel fluoride, rubidium fluoride, silicon fluoride, silver fluoride, thallium fluoride, thallium fluoride, thorium fluoride, tin fluoride, uranium fluoride, tungsten fluoride, selenium fluoride, tellurium fluoride, and combinations thereof.

7. The cathode of claim 1, wherein the coating comprises a phosphate compound selected from the group consisting of zinc phosphate, aluminum phosphate, titanium phosphate, hafnium phosphate, zirconium phosphate, lithium phosphate, lanthanum phosphate, barium phosphate, bismuth phosphate, bismuth phosphate, calcium phosphate, cerium phosphate, cerium phosphate, chromium phosphate, chromium phosphate, chromium phosphate, chromium phosphate, cobalt phosphate, cobalt phosphate, cobalt phosphate, copper phosphate, copper phosphate, iron phosphate, iron phosphate, lead phosphate, magnesium phosphatephosphate, manganese phosphate, mercury phosphate, nickel phosphate, rubidium phosphate, silicon phosphate, silver phosphate, thallium phosphate, thallium phosphate, thorium phosphate, tin phosphate, uranium phosphate, tungsten phosphate, selenium phosphate, tellurium phosphate, and combinations thereof.

8. The cathode of claim 1, wherein the coating comprises a pure metal or metalloid selected from the group consisting of zinc, copper, carbon, gold, magnesium, aluminum, silicon, calcium, titanium, vanadium, chromium, manganese, iron, cobalt, nickel, carbon and gallium.

9. The cathode of claim 1, wherein the coating comprises a sulfide compound selected from the group consisting of zinc sulfide, aluminum sulfide, titanium sulfide, hafnium sulfide, zirconium sulfide, lithium sulfide, lanthanum sulfide, barium sulfide, bismuth sulfide, bismuth sulfide, calcium sulfide, cerium sulfide, cerium sulfide, chromium sulfide, chromium sulfide, chromium sulfide, chromium sulfide, cobalt sulfide, cobalt sulfide, cobalt sulfide, copper sulfide, copper sulfide, iron sulfide, iron sulfide, lead sulfide, magnesium sulfide, manganese sulfide, mercury sulfide, nickel sulfide, rubidium sulfide, silicon sulfide, silver sulfide, thallium sulfide, thallium sulfide, thorium sulfide, tin sulfide, uranium sulfide, tungsten sulfide, selenium sulfide, tellurium sulfide, and combinations thereof.

10. The cathode of claim 1, wherein the coating has a thickness in a range from about 0.1 nanometers to about 50 microns, or from about 0.1 nm to about 500 nm.

11. The cathode of claim 1, wherein the coating is substantially homogeneous and conformal on the substrate.

12. The cathode of claim 1, wherein the manganese oxide is gamma-MnO₂.

13. A zinc-ion battery comprising:
the manganese oxide cathode of claim 1;
an anode comprising zinc;
a separator for separating the cathode from the anode; and
an aqueous electrolyte.

14. The zinc-ion battery of claim 13, wherein the electrolyte has a pH ranging from about 4 to about 7.

15. The zinc-ion battery of claim 13, wherein the electrolyte comprises an additive that lowers a freezing point of the electrolyte.

16. The zinc-ion battery of claim 13, wherein the electrolyte comprises zinc ions, manganese ions, and sulfate ions.

17. The zinc-ion battery of claim 13, wherein the electrolyte comprises propylene glycol.

18. The zinc-ion battery of claim 13, wherein the electrolyte comprises ions from salts selected from the group consisting of zinc chloride, calcium chloride, sodium chloride and magnesium chloride.

19. The zinc-ion battery of claim 13, wherein the anode comprises a coating comprising an oxide compound, a nitride compound, a fluoride compound, a phosphate compound, a sulfide compound, or any combination thereof.

20. The zinc-ion battery of claim 13, wherein the anode comprises a coating comprising a compound having one or more hydroxyl or carboxyl groups; a saccharide, oligosaccharide, or polysaccharide; a (meth)acrylic acid or (meth)acrylate and polymers thereof; a nitride compound with a N—H group; NO₂; a compound having a carbon-nitrogen structure; a phosphate compound; or any combination thereof.

21-29. (canceled)
